(19) United States
(12) Patent Application Publication
(10) Pub. No.: US 2012/0217553 A1
(43) Pub. Date: Aug. 30, 2012

(54) SEMICONDUCTOR STRUCTURE AND METHOD FOR FORMING THE SAME

(75) Inventors: Zhijiong Luo, Poughkeepsie, NY (US); Haizhou Yin, Poughkeepsie, NY (US); Huilong Zhu, Poughkeepsie, NY (US)

(73) Assignee: INSTITUTE OF MICROELECTRONICS, CHINESE ACADEMY OF SCIENCES, BEIJING (CN)

(21) Appl. No.: 13/063,737

(22) PCT Filed: Jun. 28, 2010
(86) PCT No.: PCT/CN10/74578

§ 371 Date: Mar. 11, 2011

(30) Foreign Application Priority Data
Dec. 15, 2009 (CN) 200910242509.6

(51) Int. Cl. H01L 29/78; H01L 21/336

(52) U.S. Cl. 257/288; 438/300; 257/E29.255; 257/E21.409

(57) ABSTRACT

The present invention provides a semiconductor structure, comprising: a substrate; a gate formed on the substrate, and a source and drain formed in the substrate and disposed at two sides of the gate; raised portions formed on the source and the drain, respectively, a height of the raised portions being approximate to a height of the gate; and a metal silicide layer and contact holes formed on the raised portions and on the gate. By virtue of the raised portions added to the source/drain in an embodiment of the present invention, the height difference between the gate and the source/drain may be decreased, such that the formation of the contact holes becomes much easier.

### FIELD OF THE INVENTION

The present invention relates to the technical field of semiconductor design and manufacturing, and more particularly, to a semiconductor structure which has raised Source/Drain(S/D) and a method for forming the semiconductor structure.

### BACKGROUND OF THE INVENTION

With the developing of the semiconductor technology, the feature size of a complementary metal oxide semiconductor (CMOS) device has been further reduced, thereby causing problems of Short Channel Effect, connection, etc., which have become a bottleneck blocking the development of the semiconductor technology. In particular, with the further reducing of feature size, it has become increasingly difficult for manufacturing contact holes for the gate and source/drain. As shown in FIG. 1, which shows a structural diagram of a CMOS device formed in the prior art, since there is height difference between the gate and the source/drain, it would be greatly difficult to form contact holes on the gate and source/drain.

### SUMMARY OF THE INVENTION

An objective of the present invention is to at least solve one of the above technical drawbacks, and in particular, to solve the problem of forming contact holes caused by a height difference between the gate and the source/drain.

In order to achieve the above objective, according to an aspect of the present invention, there is provided a semiconductor structure, comprising: a substrate; a gate formed on the substrate, and a source and drain formed in the substrate and disposed at two sides of the gate; raised portions formed on the source and drain, respectively, a height of the raised portions being approximate to a height of the gate; and a metal silicide layer and contact holes formed on the raised portions and on the gate.

In an embodiment of the present invention, there further includes: a first sidewall spacer, a second sidewall spacer, and a third sidewall spacer, formed between the gate and the raised portions, wherein the third sidewall spacer partially covers the raised portions on the source and drain.

In an embodiment of the present invention, the first sidewall spacer, the second sidewall spacer, and the third sidewall spacer are higher than the gate and the raised portions so as to form a recess on the gate.

In an embodiment of the present invention, nitride is filled in the recess, and the contact holes penetrate the nitride to contact with the metal silicide on the gate.

In an embodiment of the present invention, there further comprises a fourth sidewall spacer formed on an internal side of the recess.

In an embodiment of the present invention, nitride is filled in the recess on which the fourth sidewall spacer is formed, and the contact holes penetrate the nitride to contact with the metal silicide on the gate.

In an embodiment of the present invention, there further comprises a fifth sidewall spacer formed on the third sidewall spacer, the fifth sidewall spacer partially covers the metal silicide on the raised portions.

In an embodiment of the present invention, the materials of the fourth sidewall spacer and the fifth sidewall spacer are different from the deposited nitride so as to increase an etching selectivity.

According to another aspect of the present invention, there is provided a method for forming the above semiconductor structure, comprising steps of: forming a substrate; forming a gate on the substrate, and forming a source and a drain in the substrate and at two sides of the gate; forming raised portions on the source and drain, respectively, wherein a height of the gate is adjusted or a height of the raised portions is controlled such that the height of the raised portions is approximate to the height of the gate; and forming a metal silicide layer and contact holes for connection on the raised portion and the gate.

In an embodiment of the present invention, after forming the gate, there further comprises: forming a relatively thick oxide cap layer on the gate.

In an embodiment of the present invention, before forming the raised portions on the source and drain, there further comprising: forming a first sidewall spacer and a second sidewall spacer on two sides of the gate and the oxide cap layer, respectively.

In an embodiment of the present invention, after forming the raised portions on the source and drain, there further comprises: forming a third sidewall spacer on the second sidewall spacers, wherein the third sidewall spacer partially covers the raised portion on the source and drain.

In an embodiment of the present invention, the adjusting the height of the gate comprises: removing the oxide cap layer to form a recess, the recess enabling the height of the raised portions to be approximate to the height of the gate.

In an embodiment of the present invention, there further comprises: filling nitride being filled in the recess, and the contact holes penetrating the nitride to contact with the metal silicide on the gate.

In an embodiment of the present invention, there further comprises: forming a fourth sidewall spacer on an internal side of the recess.

In an embodiment of the present invention, there further comprises: forming a fifth sidewall spacer on the third sidewall spacer, the fifth sidewall spacer partially covering the metal silicide on the raised portions.

In an embodiment of the present invention, the materials of the fourth sidewall spacer and the fifth sidewall spacer are different from the deposited nitride so as to form contact holes by a manner of self-alignment.

In an embodiment of the present invention, after forming the third sidewall spacer, there further comprises: removing the oxide cap layer and the first sidewall spacer, second sidewall spacer, and third sidewall spacer on two sides of the oxide cap layer.

By virtue of adding a raised portion to the source/drain, in an embodiment of the present invention, the height difference between the gate and the source/drain can be decreased, such that the formation of contact holes becomes much easier. Further, in other embodiments of the present invention, a recess formed being surrounded by the first to third sidewall spacers on the gate may also be used to reduce the height difference between the gate and the source/drain. Further, the recess may also be used to form a fourth sidewall spacer and fifth sidewall spacer which are smaller. The smaller fourth and fifth sidewall spacers can provide an additional advantage for the reactive ion etch (RIE), and with the fourth and fifth sidewall spacers, a self-aligned contact holes process can be employed. Additionally, a tall gate with a recess can provide additional strain benefits.

Additional aspects and advantages of the present invention will be partially provided in the following description, and will partially become apparent from the following description or understood through implementation of the present invention.

### BRIEF DESCRIPTION OF THE DRAWINGS

The above and/or additional aspects and advantages of the present invention will become apparent and easily understood from the following description on the embodiments with reference to the accompanying drawings, and the drawings of the present invention are schematic and are thus not drawn proportionally. In the drawings,

FIG. 1 is a structural diagram of a CMOS device formed in the prior art;

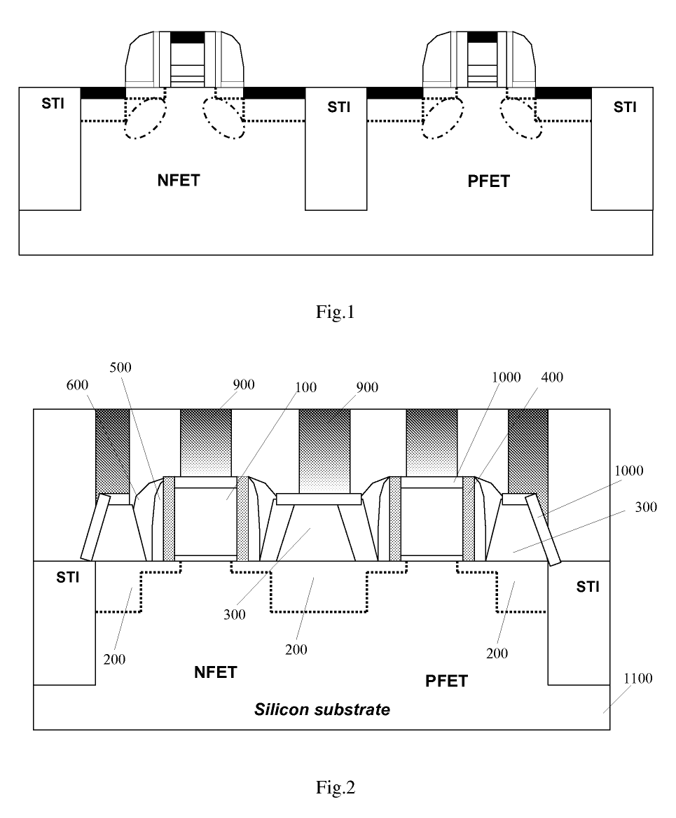

FIG. 2 shows a diagram of a semiconductor structure having a raised portion on a source/drain according to the first embodiment of the present invention;

FIG. 3 shows a diagram of a semiconductor structure having a raised portion on a source/drain according to the second embodiment of the present invention;

FIG. 4 shows a diagram of a semiconductor structure having a raised portion on a source/drain according to the third embodiment of the present invention;

FIGS. 5-7 show sectional views of intermediate steps of a method for forming a semiconductor structure of the first embodiment according to the fourth embodiment of the present invention;

FIGS. 8-12 show sectional views of intermediate steps of a method for forming a semiconductor structure according to the fifth embodiment of the present invention; and

FIGS. 13-14 show sectional views of intermediate steps of a method for forming a semiconductor structure according to the sixth embodiment of the present invention.

### DETAILED DESCRIPTION OF THE INVENTION

Hereinafter, the embodiments of the present invention will be described in detail. Examples of the embodiments are illustrated in the drawings, across which same or like reference numbers indicate same or like elements or elements with same or like functions. The embodiments described hereinafter with reference to the drawings are exemplary and only for explaining the present invention, which should not be interpreted as limitations to the present invention.

The following disclosure provides a plurality of different embodiments or examples to achieve different structures of the present invention. To simplify the disclosure of the present invention, description of the components and structures of specific examples is given below. Of course, they are only illustrative and not limiting the present invention. Moreover, in the present invention, reference numbers and/or letters may be repeated in different embodiments. Such repetition is for the purposes of simplification and clearness, and does not signify the relationship between respective embodiments and/or structures being discussed. In addition, the present invention provides various examples for specific process and materials. However, it is obvious for a person of ordinary skill in the art that other process and/or materials may alternatively be utilized. Furthermore, the following structure in which a first object is “on” a second object may include an embodiment in which the first object and the second object are formed to be in direct contact with each other, and may also include an embodiment in which another object is formed between the first object and the second object such that the first and second objects might not be in direct contact with each other.

The present invention mainly balances the height difference between the gate and the source/drain through a raised portion (raised S/D) formed on the source/drain, such that the formation of contact holes becomes much easier and connection problems caused by constantly scaling of feature size are alleviated. The present invention provides a plurality of embodiments having a raised portion. In other embodiments, preferably, a recess may be also be formed at the top of the gate, and the height difference between the gate and source/drain may also be balanced through the recess, which, additionally, may also provide additional strain. Further, in other embodiments, a smaller sidewall spacer may be further formed with the recess on the gate, thereby an advantage for a reactive ion etch (RIE) can be brought and meanwhile a self-alignment process can be adopted. Hereinafter, the above ideas of the present invention will be introduced through the embodiments. It should be noted that the following embodiments are only preferred embodiments of the present invention, and it is not intended that the present invention can only be implemented through the following embodiments. The skilled in the art may make equivalent modifications or replacements to the following embodiments based on the ideas of the present invention, and such equivalent modifications or replacements should fall within the protection scope of the present invention.

### Embodiment 1

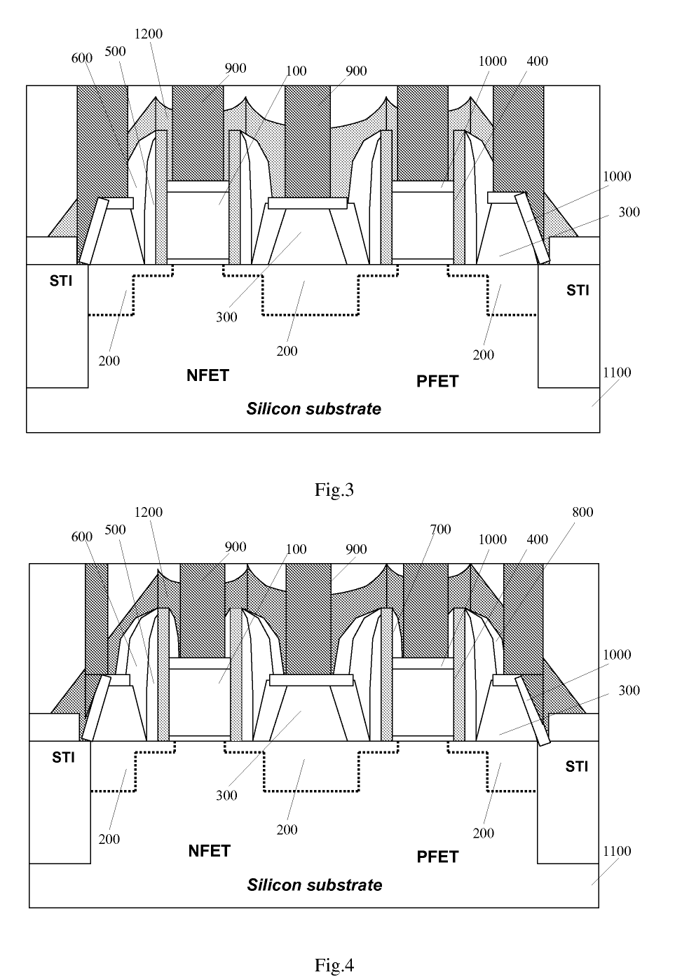

FIG. 2 shows a diagram of a semiconductor structure having a raised portion on a source/drain according to the first embodiment of the present invention. It should be noted that in this embodiment, a complementary metal oxide semiconductor (CMOS) structure is taken as an example for illustration. However, this embodiment and all embodiments hereinafter are not limited to the CMOS structure, and other structures may also be applied to various embodiments of the present invention, which will not be enumerated here. The semiconductor structure comprises a substrate 1100, a gate 100 formed on the substrate 1100, a source and drain 200 formed in the substrate 1100 and disposed at two sides of the gate 100, and further, a raised portion 300 formed on the source and drain 200, respectively. A height of the raised portion 300 can be approximate to a height of the gate 100. In an embodiment of the present invention, a height of the raised portion 300 is slightly lower than the height of the gate 100, as shown in FIG. 2. In this embodiment, a first sidewall spacer 400, a second sidewall spacer 500, and a third sidewall spacer 600 are formed at both sides of the gate 100, wherein the third sidewall spacer 600 partially covers the source and drain 200. In an embodiment of the present invention, there are two sidewall spacers at two sides of the gate 100, and the skilled in the art may increase or decrease the number of sidewall spacers as required, which should fall within the protection scope of the present invention. This structure further comprises a metal silicide layer 1000 and contact holes 900 formed on the raised portion 300 and gate 100.

### Embodiment 2

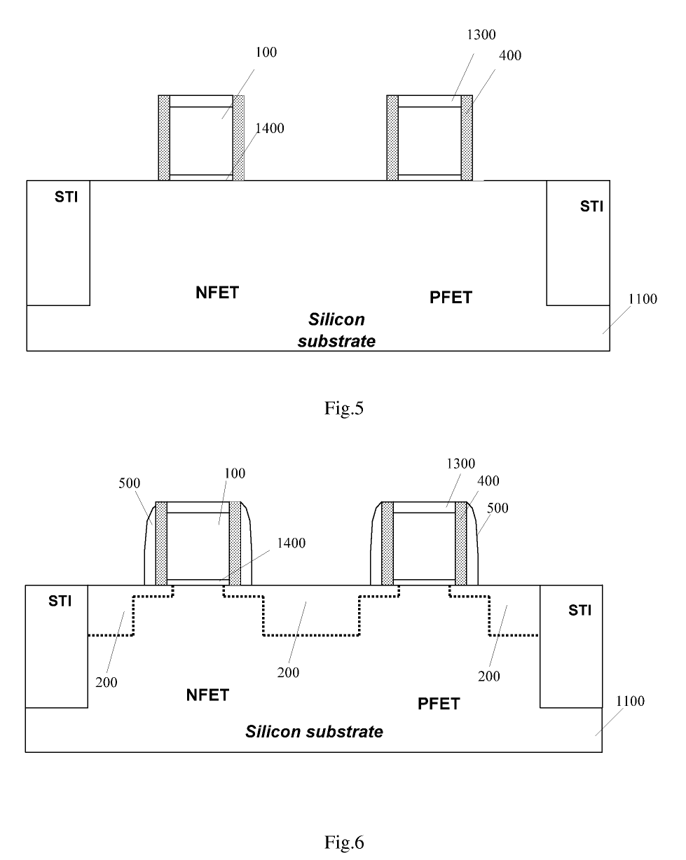

FIG. 3 shows a diagram of a semiconductor structure having a raised portion on a source/drain according to the second embodiment of the present invention. Different from Embodiment 1, in this embodiment, a recess is further formed on the gate 100, the recess being formed by the gate 100 and the first sidewall spacer 400, the second sidewall spacer 500, and the third sidewall spacer 600 which are higher than the gate 100. With the recess, the height difference between the gate and the source/drain may be effectively decreased, and further, with the recess, a better strain property can be provided.

### Embodiment 3

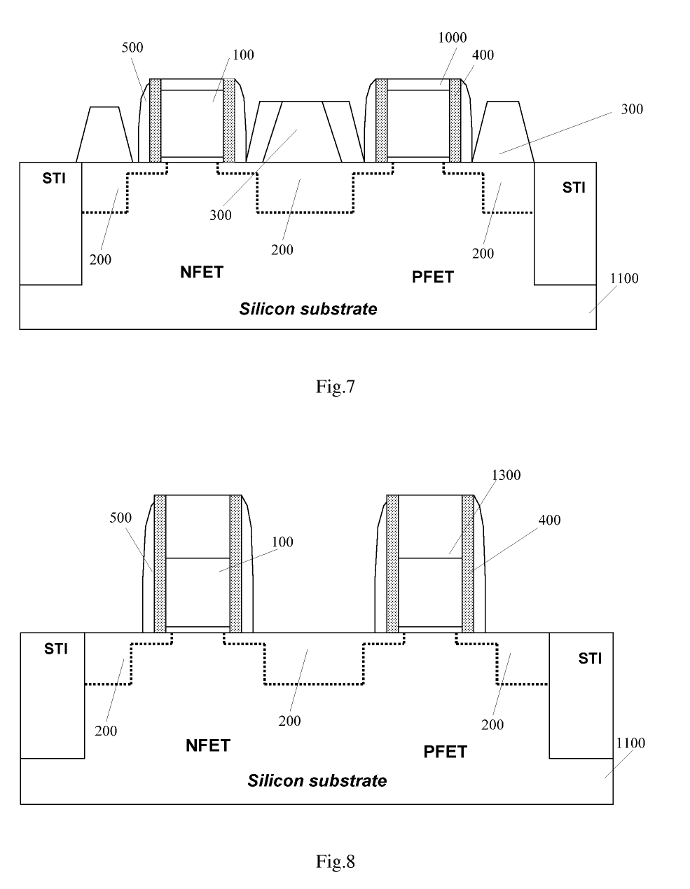

FIG. 4 shows a diagram of a semiconductor structure having a raised portion on a source/drain according to the third embodiment of the present invention. On the basis of Embodiment 2, in this embodiment, a smaller sidewall spacer is formed based on the recess on the gate 100. Specifically, a fourth sidewall spacer 700 is formed on the first wall 400 in the internal side of the recess. In this embodiment, a fifth sidewall spacer 800 may be further formed on the third sidewall spacer 600 outside the recess, the fifth sidewall spacer 800 partially covering the metal silicide layer 1000 on the raised portion 300. In an embodiment of the present invention, the fourth sidewall spacer 700 and the fifth sidewall spacer 800 comprise oxide. In this embodiment, the materials of the fourth sidewall spacer 700 and the fifth sidewall spacer 800 are different from the deposited nitride so as to enhance the etching selectivity, thereby the contact holes may be formed by adopting the self-alignment process. In another embodiment of the present invention, the materials of the fourth sidewall spacer 700 and the fifth sidewall spacer 800 are also different from the material of the third sidewall spacer 600. The fourth sidewall spacer 700 and the fifth sidewall spacer 800 as provided in this embodiment may provide an additional advantage for RIE, and through the fourth sidewall spacer 700 and the fifth sidewall spacer 800, the contact holes can be formed by adopting the self-alignment process.

In order to better understand the semiconductor structure as proposed by the present invention, the present invention further provides embodiments of methods for forming the semiconductor structure. It should be noted that the skilled in the art may choose a variety of manufacturing processes based on the above semiconductor structure, for example, different types of product lines, different processing flows, etc. However, if a semiconductor structure manufactured by these processes adopts a substantially same structure and achieves a substantially same effect as the above structure of the present invention, it should also fall within the protection scope of the present invention. In order to better understand the present invention, a method and process for forming the above structure of the present invention will be described in detail. It should be also noted that the following steps are only schematic, not for limiting the present invention, and they may also be implemented by the skilled in the art through other processes.

### Embodiment 4

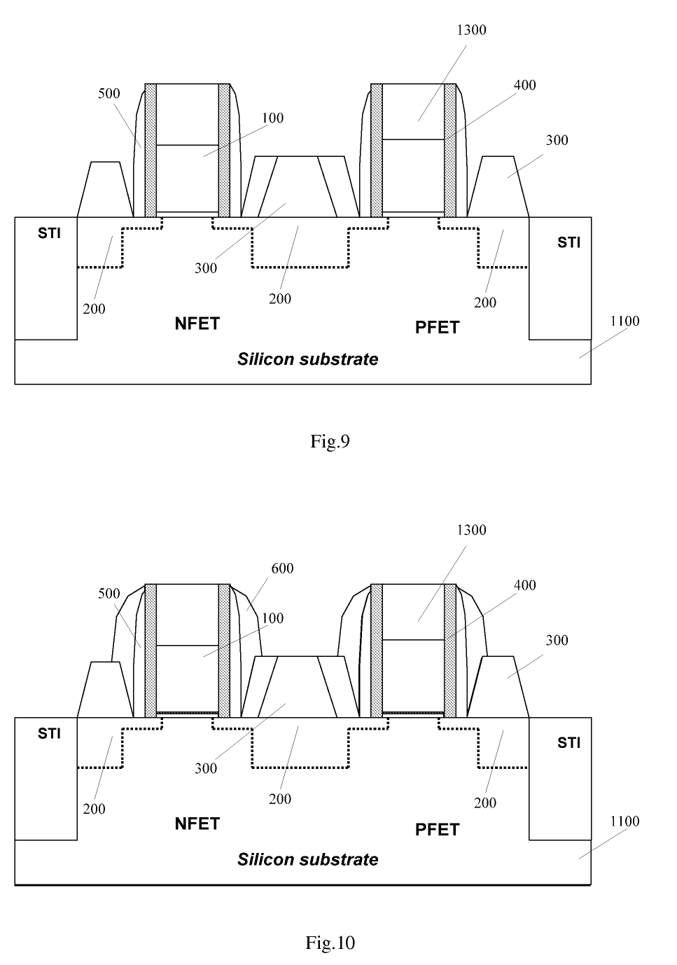

FIGS. 5-7 show sectional views of intermediate steps of a method for forming a semiconductor structure of the first embodiment according to the fourth embodiment of the present invention. This embodiment comprises steps of:

In step 401, a substrate 1100 is formed.

In step 402, a gate stack is formed on the substrate 1100 and a first sidewall spacer 400 is formed at both sides of the gate stack. In an embodiment of the present invention, the gate stack comprises a gate dielectric layer 1400, a gate 100 formed on the gate dielectric layer 1400, and an oxide cap layer 1300 formed on the gate 100, as shown in FIG. 5. The structure of the above gate stack is only an example of the present invention, and a gate stack of other structures may also be applied in the present invention, which, therefore, should also fall within the protection scope of the present invention.

In step 403, a second sidewall spacer 500 is formed on the first sidewall spacer 400 and implanted to form a source and drain 200, as shown in FIG. 6.

In step 404, raised portions 300 are formed on the source and drain 200, respectively, as shown in FIG. 7. In an embodiment of the present invention, a raised portion 300 may be formed by epitaxial growth (Epi). In this embodiment, the raised portions 300 may be formed all together through the process of embedding Si—Ge in the source and drain (eSiGe) technique or Si:C technique.

In step 405, a third sidewall spacer 600 is formed on the second sidewall 500, the third sidewall spacer 600 partially covering the raised portion 300 on the source and drain 200.

In step 406, a metal silicide layer 600 and contact holes 900 are formed on the raised portion 300 and the gate 200 for connection, as shown in FIG. 2.

### Embodiment 5

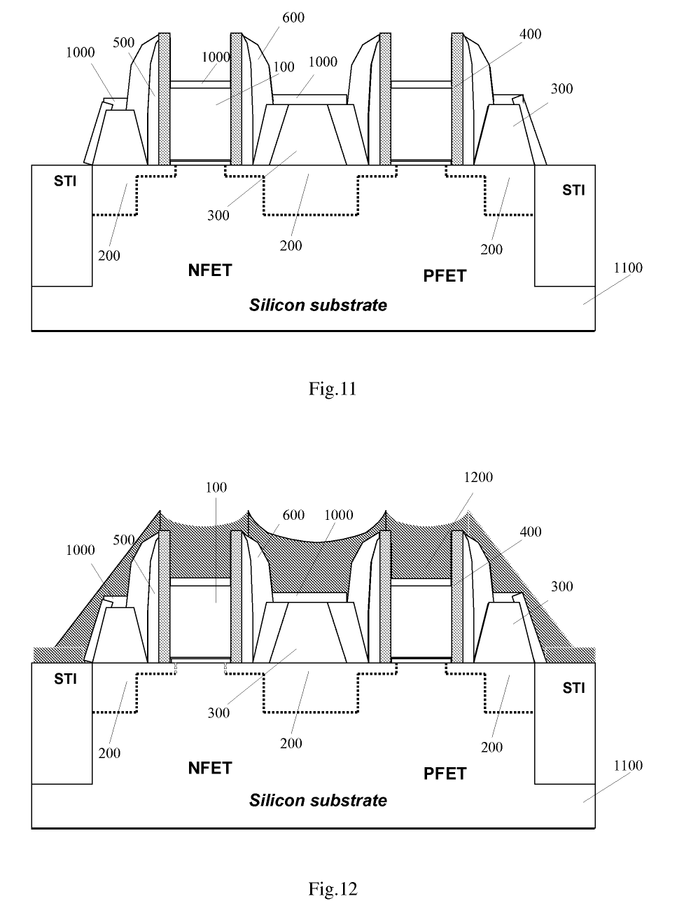

FIGS. 8-12 show sectional views of intermediate steps of a method for forming a semiconductor structure according to the fifth embodiment of the present invention. This embodiment comprises steps of:

In step 501, a substrate 1100 is formed.

In step 502, a tall gate stack is formed on the substrate 1100, a first sidewall spacer 400 and a second sidewall spacer 500 are formed at both sides of the gate stack, and a source and drain 200 are formed, as shown in FIG. 8. In an embodiment of the present invention, a tall gate stack means that a layer of relatively thick oxide cap layer 1300 are formed on the gate 100, and in this embodiment, the thickness of the oxide cap layer 1300 is higher than that of the oxide cap layer in Embodiment 4. In this embodiment, a purpose for forming the thicker oxide cap layer 1300 is to form a recess on the gate (this recess will be illustrated in the following steps), and the skilled in the art may appreciate that there are a plurality of methods for forming the recess, and all of these methods can implement the present invention and thus should fall within the protection scope of the present invention.

In step 503, raised portions 300 are formed on the source and drain 200, respectively, as shown in FIG. 9. In an embodiment of the present invention, a raised portion 300 may be formed by the method of epitaxial growth (Epi). In this embodiment, the raised portions 300 may be formed all together by the eSiGe or Si:C process.

In step 504, a third sidewall spacer 600 is formed on the second sidewall 500, the third sidewall spacer 600 partially covering the raised portions 300 on the source and drain 200, as shown in FIG. 10.

In step 505, a recess on the gate 100 is formed by removing the oxide cap layer 1300 on the gate 100. The recess is advantageous to decrease the height difference between the gate 100 and the source and drain 200 and brings benefits to improving the strain. A metal silicide layer 1000 is formed on the gate 100 and the raised portions 300, as shown in FIG. 11.

In step 506, nitride layer 1200 is deposited, as shown in FIG. 12.

In step 507, contact holes 900 are formed for connecting the raised portions 300 on the gate 100 and the source and drain 200, as shown in FIG. 3.

In another Embodiment 6 of the present invention, the recess mentioned in the above embodiment may also be used to form two smaller sidewall spacers, the first several steps of this embodiment are identical to steps 501-505 of Embodiment 5, and after step 505, this embodiment further comprises steps of:

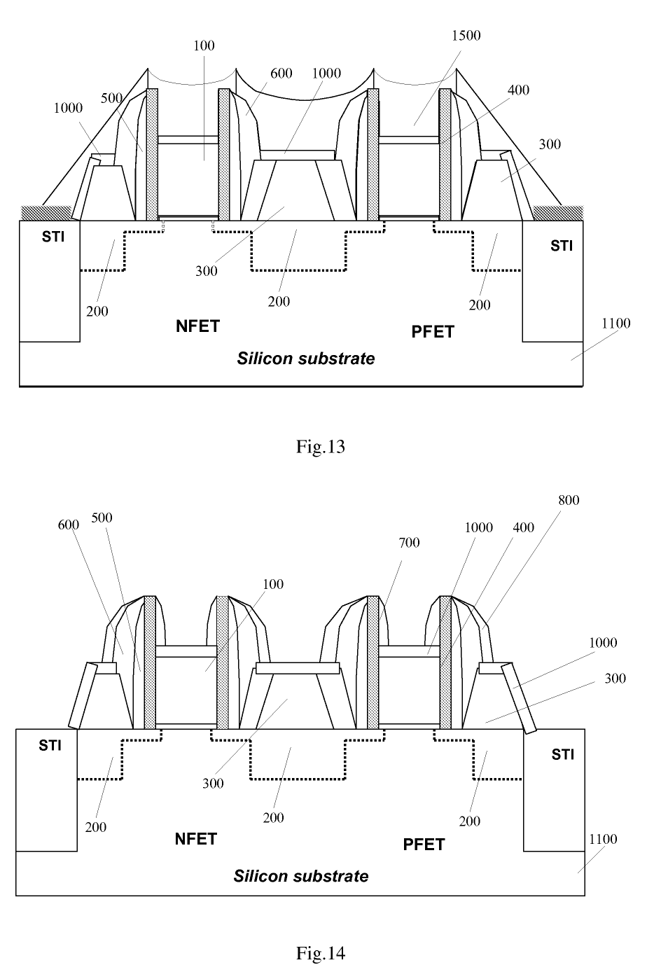

In step 601, an oxide layer 1500 is deposited with a nitride lining, as shown in FIG. 13.

In step 602, a fourth sidewall spacer 700 and a fifth sidewall spacer 800 are formed by RIE etching, as shown in FIG. 14, wherein the fifth sidewall spacer 800 partially covers the raised portions 300 on the source and drain 200. The fourth sidewall spacer 700 and the fifth sidewall spacer 800 as provided in this embodiment may provide an additional advantage for RIE. Furthermore, through the fourth sidewall spacer 700 and the fifth sidewall spacer 800, contact holes may be formed by adopting a self-alignment process.

In step 603, a nitride layer 1200 is deposited and contact holes 900 are formed by for connecting the raised portions 300 on the gate 100 and the source and drain 200, as shown in FIG. 4.

As an alternative solution of the present invention, the recess formed in the above steps may be also eliminated to obtain a structure similar to Embodiment 1, which will not be detailed here.

By virtue of the raised portions added to the source/drain in embodiments the present invention, the height difference between the gate and the source/drain may be decreased, such that the forming of the contact holes becomes much easier. Further, in other embodiments of the present invention, a recess formed being surrounded by the first to third sidewall spacers on the gate may also be used to decrease the height difference between the gate and the source/drain. Moreover, the recess may also be used to form a smaller fourth sidewall spacer and fifth sidewall spacer, the smaller fourth sidewall spacer and fifth sidewall spacer can provide an additional advantage for reactive ion etch (RIE), and a self-aligned contact holes process may be employed with the fourth sidewall spacer and the fifth sidewall spacer. Additionally, a tall gate with a recess can provide benefits to the strain.

Though embodiments of the present invention have been illustrated and described, to a person of ordinary skill in the art, it may be understood that various variations, modifications, alternations and transformations may be conducted to these embodiments without departing from the principle and spirit of the present invention, and the scope of the present invention is defined by the appending claims and their equivalents.

1. A semiconductor structure, comprising:
a substrate;
a gate formed on the substrate,
a source and drain formed in the substrate and disposed at both sides of the gate;
raised potions formed respectively on the source and drain, the height of the raised portions being substantially the same as the height of the gate; and
a metal silicide layer and contact holes formed on the raised portions and on the gate.

2. The semiconductor structure according to claim 1, further comprising:
a first sidewall spacer, a second sidewall spacer, and a third sidewall spacer formed between the gate and raised portions, wherein the first sidewall spacer surrounds the gate, the second sidewall spacer surrounds the first sidewall spacer, and the third sidewall spacer surrounds the second sidewall spacer and partially covers the raised portions on the source and drain.

3. The semiconductor structure according to claim 2, wherein, the height of the first sidewall spacer, the second sidewall spacer, and the third sidewall spacer is higher than the that of the gate and the raised portions, so as to form a recess on the gate.

4. The semiconductor structure according to claim 3, wherein nitride is filled in the recess, and the contact holes penetrate through the nitride to contact with the metal silicide layer on the gate.

5. The semiconductor structure according to claim 3, further comprising a fourth sidewall spacer formed on the inner side of the recess.

6. The semiconductor structure according to claim 5, wherein nitride is filled in the recess on the inner side of which the fourth sidewall spacer is formed, and the contact holes penetrate through the nitride to contact with the metal silicide layer on the gate.

7. The semiconductor structure according to claim 6, further comprising a fifth sidewall spacer formed on the third sidewall spacer, the fifth sidewall spacer partially covers the metal silicide layer on the raised portions.

8. The semiconductor structure according to claim 7, wherein the materials of the fourth sidewall spacer and the fifth sidewall spacer are different from the deposited nitride, so as to improve etching selectivity.

9. A method for forming a semiconductor structure, comprising steps of:
forming a substrate;
forming a gate on the substrate,
forming a source and drain in the substrate and at both sides of the gate;
forming raised portions on the source and drain, wherein the height of the gate is adjusted or the height of the raised portions is controlled, such that the height of the raised portions is approximate to the height of the gate;
forming a metal silicide layer and contact holes for connection on the raised portions and on the gate.

10. The method according to claim 9, after forming the gate, further comprising:
forming a relatively thick oxide cap layer on the gate.

11. The method according to claim 10, before forming the raised portions on the source and drain, further comprising:
forming a first sidewall spacer and a second sidewall spacer on the sidewalls of the gate and the oxide cap layer, respectively.

12. The method according to claim 11, after forming the raised portions on the source and drain, further comprising:
forming a third sidewall spacer on the second sidewall spacer, wherein the third sidewall spacer partially covers the raised portions on the source and drain.

13. The method according to claim 12, wherein adjusting the height of the gate further comprises:
removing the oxide cap layer to form a recess, the recess enabling the height of the raised portions to be substantially the same as the height of the gate.

14. The method according to claim 13, further comprising:
filling nitride in the recess, the contact holes penetrating through the nitride to contact with the metal silicide layer on the gate.

15. The method according to claim 13, further comprising:
forming a fourth sidewall spacer on an inner side of the recess.

16. The method according to claim 13, further comprising:
forming a fifth sidewall spacer on the third sidewall spacer, the fifth sidewall spacer partially covering the metal silicide layer on the raised portions.

17. The method according to claim 15, wherein the materials of the fourth sidewall spacer and the fifth sidewall spacer are different from the deposited nitride, so as to form contact holes by self-alignment.

18. The method according to claim 12, after forming the third sidewall spacer, further comprising:
removing the oxide cap layer, and the first sidewall spacer, the second sidewall spacer, and the third sidewall spacer on both sides of the oxide cap layer.

19. The method according to claim 16, wherein the materials of the fourth sidewall spacer and the fifth sidewall spacer are different from the deposited nitride, so as to form contact holes by self-alignment.
